(19) United States
(12) Patent Application Publication
(10) Pub. No.: US 2023/0130998 A1
(43) Pub. Date: Apr. 27, 2023

(54) PHOTOACID GENERATOR AND PHOTORESIST COMPOSITION INCLUDING THE SAME

(71) Applicant: SAMSUNG ELECTRONICS CO., LTD., Suwon-si (KR)

(72) Inventors: Yechan KIM, Hwaseong-si (KR); Hyunwoo KIM, Seongnam-si (KR); Jicheol PARK, Anyang-si (KR); Honggu IM, Hwaseong-si (KR)

(21) Appl. No.: 17/966,970

(22) Filed: Oct. 17, 2022

(30) Foreign Application Priority Data
Oct. 18, 2021 (KR) 10-2021-0138838

(51) Int. Cl. G03F 7/06; G03F 7/039

(52) U.S. Cl. CPC G03F 7/066; G03F 7/0392

(57) ABSTRACT

A photoacid generator (PAG) and a photoresist composition including the PAG, the PAG being represented by Formula I below,

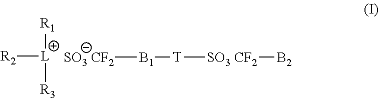

### CROSS-REFERENCE TO RELATED APPLICATION

This application is based on and claims priority under 35 U.S.C. § 119 to Korean Patent Application No. 10-2021-0138838, filed on Oct. 18, 2021, in the Korean Intellectual Property Office, the disclosure of which is incorporated by reference herein in its entirety.

### BACKGROUND

### 1. Field

Embodiments relate to a photoacid generator and a photoresist composition including the same.

### 2. Description of the Related Art

According to the tendency to downscale semiconductor devices, extreme ultraviolet (EUV) light has been used as a light source of an exposure apparatus to form a fine photoresist pattern on a semiconductor substrate. Extreme ultraviolet light increases energy per photon by about 14 times compared to existing ArF or KrF light, but the number of photons in EUV light decreases by about 14 times in the same amount of light compared to ArF or KrF light.

### SUMMARY

The embodiments may be realized by providing a photoacid generator (PAG) represented by Formula I below,

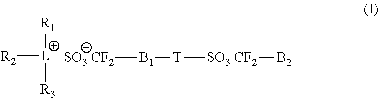

wherein in Formula I, L is S or I, and when L is I, R₃ is omitted, R₁, R₂, and R₃ are each independently a C1 to C10 alkyl group, C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom, two of R₁, R₂, and R₃ are bonded to each other to form a ring together with L, B₁ includes two or more ester groups, and is a monovalent or divalent hydrocarbon group which is substituted with a heteroatom or intervened with a heteroatom, B₂ is a monovalent or divalent C1 to C20 hydrocarbon group which is substituted with a heteroatom or intervened with a heteroatom, and T is an acid-sensitive group.

The embodiments may be realized by providing a photoacid generator represented by Formula IV below,

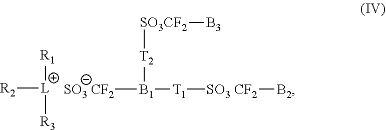

wherein in Formula IV, L is S or I, and when L is I, R₃ is omitted, R₁, R₂, and R₃ are each independently a C1 to C10 alkyl group, a C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom, two of R₁, R₂, and R₃ are bonded to each other to form a ring together with L, B₁ includes three or more ester groups, and is a monovalent or divalent hydrocarbon group which is substituted with a heteroatom or intervened with a heteroatom, B₂ and B₃ are each independently a monovalent or divalent C1 to C20 hydrocarbon group which is substituted with a heteroatom or intervened with a heteroatom, and T₁ and T₂ are each independently an acid-sensitive group.

The embodiments may be realized by providing a photoresist composition including a photosensitive resin; a photoacid generator represented by Formula I, below; and a solvent capable of dissolving the photosensitive resin and the photoacid generator,

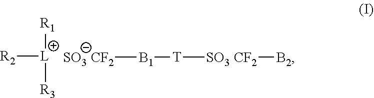

wherein in Formula I, L is S or I, and when L is I, R₃ is omitted, R₁, R₂, and R₃ are each independently a C1 to C10 alkyl group, C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom, two of R₁, R₂, and R₃ are bonded to each other to form a ring together with L, B₁ includes two or more ester groups, and is a monovalent or divalent hydrocarbon group which is substituted with a heteroatom or intervened with a heteroatom, B₂ is a monovalent or divalent C1 to C20 hydrocarbon group which is substituted with a heteroatom or intervened with a heteroatom, and T is an acid-sensitive group.

### BRIEF DESCRIPTION OF THE DRAWINGS

Features will be apparent to those of skill in the art by describing in detail exemplary embodiments with reference to the attached drawings in which:

FIGS. 1A through 1H are cross-sectional views of stages in a method of manufacturing a vertical semiconductor device, according to an embodiment.

### DETAILED DESCRIPTION

An example embodiment provides a photoacid generator, which may be represented by, e.g., Formula I.

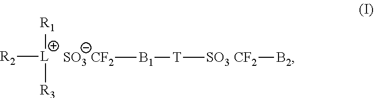

In Formula I, L may be, e.g., S or I. In an implementation, when L is I, R₃ may be omitted. R₁, R₂, and R₃ may each independently be or include, e.g., a linear, cyclic, or branched C1 to C10 alkyl group, a linear, cyclic, or branched C1 to C10 alkoxy group, a linear, cyclic, or branched C2 to C10 alkenyl group, a linear, cyclic, or branched C2 to C10 alkynyl group, a C6 to C18 aryl group, a C7 to C18 arylalkyl group, or a C7 to C18 alkylaryl group. In an implementation, R₁, R₂, and R₃ may each independently be substituted with a heteroatom or intervened with a heteroatom. In an implementation, R₁, R₂, and R₃ may be separate, or two of R₁, R₂, and R₃ may be bonded to each other to form a ring together with a sulfur atom or an iodine atom (e.g., with L). B₁ may include, e.g., two or more ester groups. In an implementation, B₁ may be or may include, e.g., a linear, cyclic, or branched monovalent or divalent group (e.g., hydrocarbon group) which may be unsubstituted or substituted with a heteroatom or intervened with a heteroatom. B₂ may be or may include, e.g., a linear, cyclic, or branched monovalent or divalent C1 to C20 hydrocarbon group, which may be unsubstituted or substituted with a heteroatom or intervened with a heteroatom. T may be or may include, e.g., an acid-sensitive group (e.g., a group that reacts with an acid).

In an implementation, R₁, R₂, and R₃ may each independently be, e.g., an alkyl group such as a methyl group, an ethyl group, an n-propyl group, an isopropyl group, an n-butyl group, a tert-butyl group, a cyclopropyl group, a cyclopentyl group, a cyclohexyl group, a cyclopropylmethyl group, a 4-methylcyclohexyl group, a cyclohexylmethyl group, a norbornyl group, or an adamantyl group; an alkenyl group such as a vinyl group, an allyl group, a propenyl group, a butenyl group, a hexenyl group, or a cyclohexenyl group, an aryl group such as a phenyl group, a naphthyl group, or a thienyl group; an aralkyl group such as a benzyl group, a 1-phenylethyl group, or a 2-phenylethyl group; or the like. In an implementation, some of hydrogen atoms in these groups may be substituted or replaced with heteroatoms such as oxygen atoms, sulfur atoms, nitrogen atoms, or halogen atoms, or may be intervened with heteroatoms (e.g., such that a heteroatom is between the group and another atom to form a—containing substituent) such as oxygen atoms, sulfur atoms, or nitrogen atoms, thereby forming or including a hydroxy group, a cyano group, a carbonyl group, an ether bond, an ester bond, a sulfonic acid ester bond, a carbonate bond, a lactone ring, a sultone ring, a carboxylic acid anhydride, a haloalkyl group, or the like.

In an implementation, when L is sulfur, L⁺(R₁R₂R₃) may have, e.g., one of the following structures.

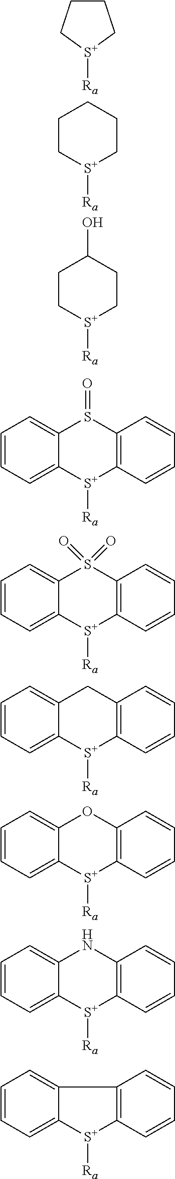

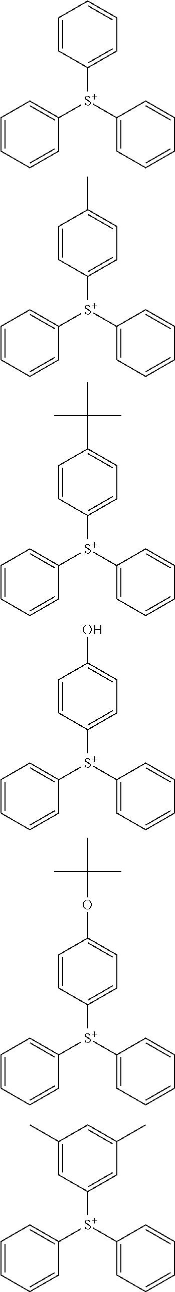 [SMILES: c1ccc([S+](c2ccccc2)c2ccccc2)cc1 ; Cc1ccc([S+](c2ccccc2)c2ccccc2)cc1 ; CC(C)(C)c1ccc([S+](c2ccccc2)c2ccccc2)cc1 ; Oc1ccc([S+](c2ccccc2)c2ccccc2)cc1 ; CC(C)(C)Oc1ccc([S+](c2ccccc2)c2ccccc2)cc1 ; Cc1cc(C)cc([S+](c2ccccc2)c2ccccc2)c1]

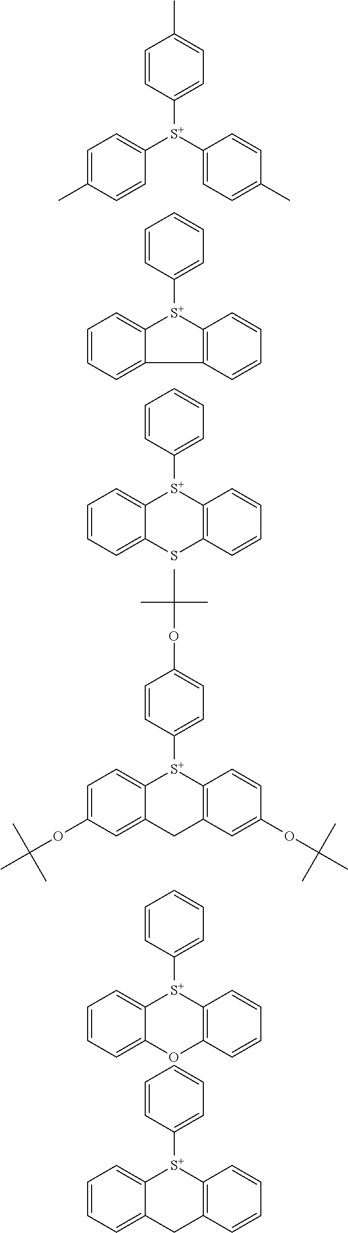

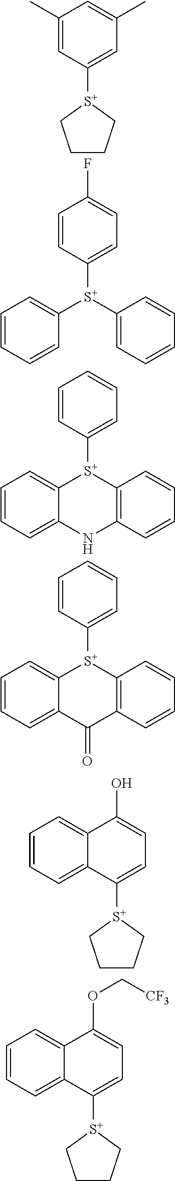

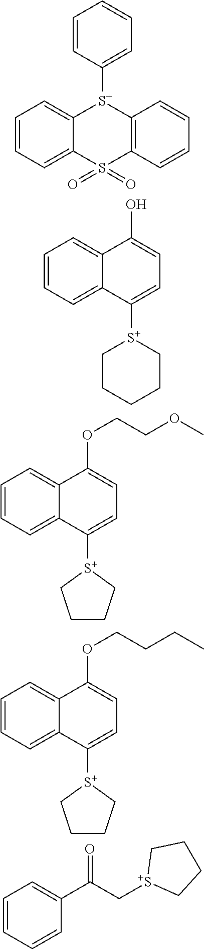 [SMILES: O=S1(=O)c2ccccc2[S+](c2ccccc2)c2ccccc21 ; Oc1ccc([S+]2CCCCC2)c2ccccc12 ; COCCOc1ccc([S+]2CCCC2)c2ccccc12 ; CCCCOc1ccc([S+]2CCCC2)c2ccccc12 ; O=C(C[S+]1CCCC1)c1ccccc1]

In an implementation, when L is iodine, L⁺(R₁R₂R₃) may be, e.g., diphenyliodonium, bis(4-methylphenyl)iodonium, bis(4-ethylphenyl)iodonium, bis(4-tert-butylphenyl)iodonium, bis(4-(1,1-dimethylpropyl)phenyl)iodonium, 4-methoxyphenylphenyliodonium, 4-tert-butoxyphenylphenyliodonium, 4-acryloyloxyphenylphenyliodonium, or 4-methacryloyloxyphenylphenyliodonium cation.

The ester groups of B₁ may connect T to SO₃CF₂. B₁ may include two or more ester groups. In an implementation, B₁ may be represented by, e.g., Formula B1a, Formula B2a, Formula B3a, or Formula B4a.

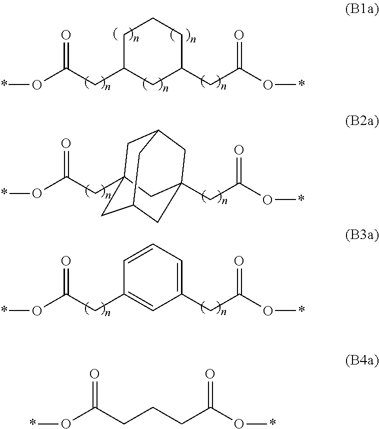

In an implementation, each n in Formula B1a, Formula B2a, Formula B3a, and Formula B4a may independently be, e.g., an integer of 0 to 10. * is a bonding site to a neighboring atom.

A functional group represented by T in the photoacid generator of Formula I may be bonded to B₁.

In an implementation, T may be desorbed from B₁ and —SO₃ groups by an acid and generate H⁺.

In an implementation, T may have a structure represented by, e.g., Formula T below.

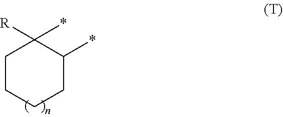

n in Formula T may be, e.g., an integer of 0 to 10. * is a bonding site to a neighboring atom.

In an implementation, the photoacid generator represented by Formula I may be, e.g., represented by Formula II below. In Formula II, the variable groups are defined the same as those of Formula I.

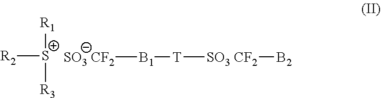

In an implementation, the photoacid generator represented by Formula I may be, e.g., represented by Formula III below. In Formula III, the variable groups are defined the same as those of Formula I.

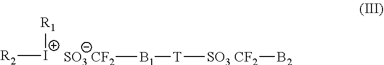

In the photoacid generator represented by Formula I, two acids may be formed with respect to or upon exposure to one photon. Here, “one photon” refers to a unit of light having minimum energy for dissociation of one SO₃⁻S⁺(R₁R₂R₃) or SO₃⁻I⁺(R₁R₂) to convert the same into one acid, e.g., into one SO₃—H⁺.

The principle of generating two acids with only one photon as described above will be described below.

Reaction Formula 1 below is a diagram conceptually illustrating a principle of generating an acid of a photoacid generator having a structure represented by Formula II.

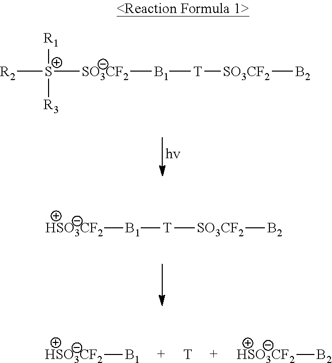

Referring to Reaction Formula 1, as a sulfonium ion is separated by incident light hν, an acid (e.g., first acid) may be generated. The generation of an acid described above may also proceed with respect to or in other nearby photoacid generators. The generated acid may act on the acid-sensitive group T attached to B₁, and the acid-sensitive group T may be desorbed or detached from B₁ and —SO₃ groups and may generate H⁺, thereby generating another one acid (e.g., a second acid).

In an implementation, a photoacid generator according to embodiments may generate two acids with exposure to only one photon, and thus may show an outstanding photosensitive effect even when a small amount thereof is used. In an implementation, in an EUV lithography process, when a photoresist composition including the photoacid generator according to the embodiments is used, the efficiency of a chemical amplification deprotection reaction may be maintained high even with EUV light, which has the small number of photons. In an implementation, the photoacid generator according to the embodiments may include an acid amplifier, and thus, a separate acid amplifier may be omitted from a photosensitive composition. In an implementation, compared to a photoacid generator or composition that separately includes an acid amplifier, the uniformity of photoresist may be upgraded, and acid generation efficiency may be further increased by an intramolecular reaction.

Another embodiment provides a photoacid generator, which may be represented by, e.g., Formula IV below.

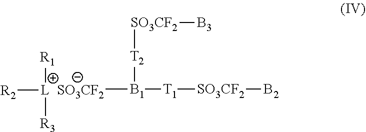

In Formula IV, L may be, e.g., S or I. In an implementation, when L is I, R₃ may be omitted. In an implementation, R₁, R₂, and R₃ may each independently be or include, e.g., one of a linear, cyclic, or branched C1 to C10 alkyl group, a linear, cyclic, or branched C1 to C10 alkoxy group, a linear, cyclic, or branched C2 to C10 alkenyl group, a linear, cyclic, or branched C2 to C10 alkynyl group, a C6 to C18 aryl group, a C7 to C18 arylalkyl group, or a C7 to C18 alkylaryl group. In an implementation, each of R₁, R₂, and R₃ may be unsubstituted or substituted with a heteroatom or intervened with a heteroatom. In an implementation, R₁, R₂, and R₃ may be separate, or any two of R₁, R₂, and R₃ may be bonded to each other to form a ring together with a sulfur atom or an iodine atom (e.g., with L). In an implementation, B₁ may include, e.g., three or more ester groups. In an implementation, B₁ may be or may include, e.g., a linear, cyclic, or branched monovalent, divalent, or trivalent group (e.g., hydrocarbon group). In an implementation, B₁ may be unsubstituted or may be substituted with a heteroatom or intervened with a heteroatom. In an implementation, B₂ and B₃ may each independently be or include, e.g., a linear, cyclic, or branched monovalent or divalent C1 to C20 group (e.g., hydrocarbon group). In an implementation, B₂ and B₃ may be unsubstituted or may be substituted with a heteroatom or intervened with a heteroatom. In an implementation, T₁ and T₂ may each independently be, e.g., an acid-sensitive group.

The ester groups of B₁ may connect T₁ and T₂ to SO₃CF₂. B₁ may include three or more ester groups. In an implementation, B₁ may be a group represented by, e.g., Formula B1b, Formula B2b, Formula B3b, Formula Bob, Formula B5b, or Formula B6b.

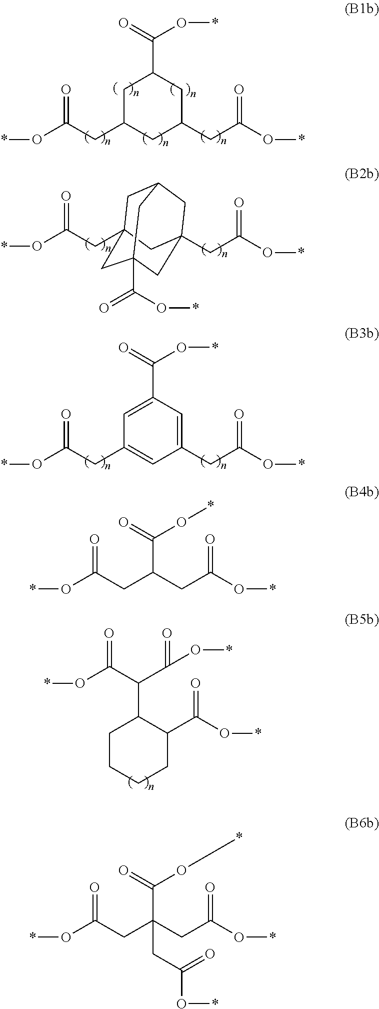

Each n in Formula B1b, Formula B2b, Formula B3b, Formula B4b, Formula B5b, and Formula B6b may independently be, e.g., an integer of 0 to 10. * is a binding site to a neighboring atom.

In an implementation, T₁ and T₂ may each independently have a structure represented by, e.g., Formula T below. In Formula T, n may be, e.g., an integer of 0 to 10 and * is a binding site to a neighboring atom.

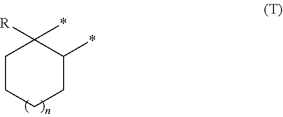

In an implementation, the photoacid generator represented by Formula IV may be, e.g., represented by Formula V below. In Formula V, the variable groups are defined the same as those of Formula IV.

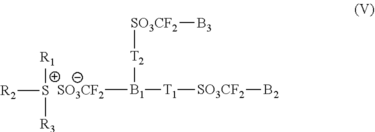

In an implementation, the photoacid generator represented by Formula IV may be, e.g., represented by Formula VI below. In Formula VI, the variable groups are defined the same as those of Formula IV.

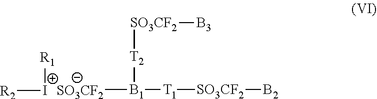

In the photoacid generator of Formula IV, three acids may be formed with respect or upon exposure to one photon.

An embodiment provides a photoresist composition including, e.g., the photoacid generator of Formula I.

The photoresist composition may include, e.g., the photoacid generator of Formula I, a photosensitive resin, and a solvent capable of uniformly dissolving the photoacid generator and the photosensitive resin. In an implementation, the photoacid generator of Formula I may be represented by Formula II. In an implementation, the photoacid generator of Formula I may be represented by Formula III.

In an implementation, the photoresist composition may further include a basic quencher. The basic quencher may be formed of a compound capable of trapping, in a non-exposed area of photoresist, an acid generated from a photoacid generator when the acid diffuses into the non-exposed area. The basic quencher may include, e.g., a primary, secondary, or tertiary amine compound, e.g., an amine compound having a hydroxy group, an ether bond, an ester bond, a lactone ring, a cyano group, or a sulfonic acid ester bond, or protecting primary or secondary amine as a carbamate group; onium salt such as sulfonium salt of carboxylic acid, iodonium salt, or ammonium salt; or a combination thereof. In an implementation, the basic quencher may include triethanol amine, triethyl amine, tributyl amine, tripropyl amine, hexamethyl disilazan, aniline, N-methylaniline, N-ethyl aniline, N-propylaniline, N, N-dimethylaniline, N, N-bis (hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or combinations thereof.

In an implementation, the photoresist composition may further include, e.g., a crosslinking agent, a leveling agent, a surfactant, an antioxidant, an adhesion improver, or the like, as needed. The photoacid generator of Formula I includes an (e.g., internal) acid amplifier, and thus, the photoresist may not include an acid amplifier as a separate molecule or component.

The photosensitive resin may include a suitable photosensitive resin for photoresist, which reacts with an acid, and thus has solubility changing respect to a developer, alternatively, may include a photosensitive polymer having a protecting group sensitive to an acid, desorbed by an acid. The photosensitive polymer may be a block copolymer or a random copolymer.

A positive photoresist may be used as the photosensitive resin. In an implementation, the positive photoresist may be a resist for extreme ultraviolet (EUV) light (13.5 nm). Extreme ultraviolet light may be generated by a plasma light source or a synchrotron radiation light source. In an implementation, the plasma light source may refer to a light source in a method of generating plasma and using light emitted by the plasma, and may include a laser produced plasma light source, a discharge produced plasma light source, or the like.

In an implementation, the positive photoresist may be, e.g., a resist for a KrF excimer laser (248 nm), a resist for an ArF excimer laser (193 nm) resist, or a resist for an F₂ excimer laser (157 nm). The positive photoresist may include, e.g., a (meth)acrylate polymer. The (meth)acrylate polymer may include, e.g., an aliphatic (meth)acrylate polymer, e.g., polymethylmethacrylate (PMMA), poly(t-butylmethacrylate), poly(methacrylic acid), poly(norbornylmethacrylate), a binary copolymer or terpolymer of repeating units of the (meth)acrylate-based polymers, or a mixture thereof. In an implementation, the (meth)acrylate polymers may be substituted with various acid-labile protecting groups. In an implementation, the protecting group may include, e.g., a tert-butoxycarbonyl (t-BOC) group, a tetrahydropyranyl group, a trimethylsilyl group, a phenoxyethyl group, a cyclohexenyl group, a tert-butoxycarbonyl methyl group, a tert-butyl group, an adamantyl group, a norbornyl group, or the like.

In an implementation, a negative photoresist may be used as the photosensitive resin. The negative photoresist may include, e.g., a novolac resin or other suitable resin, and may be obtained by reacting, e.g., a compound of phenols and aldehydes or ketones in the presence of an acidic catalyst.

Examples of the phenolic compound may include phenol, orthocresol, methacresol, paracresol, 2,3-dimethylphenol, 3,4-dimethylphenol, 3,5-dimethylphenol, 2,4-dimethylphenol, and 2,6-dimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol, 2-Isopropylphenol, 2-methoxy-5-methylphenol, 2-t-butyl-5-methylphenol, thymol, isothymol, and the like. The phenolic compounds may be used alone or in combination of two or more types.

Examples of the aldehyde compound may include formaldehyde, formalin, paraformaldehyde, trioxane, acetaldehyde, propylaldehyde, benzaldehyde, phenylacetaldehyde, α-phenylpropylaldehyde, β-phenylpropylaldehyde, o-hydroxygenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, terephthalic acid aldehyde, and the like. The aldehyde compounds may be used alone or in combination of two or more types.

Examples of the ketone compound may include acetone, methyl ethyl ketone, diethyl ketone, and diphenyl ketone. The ketone compounds may be used alone or in combination of two or more types.

The photosensitive resin may have a weight average molecular weight of, e.g., about 1,000 to about 500,000 when measured by gel permeation chromatography by using polystyrene as a standard.

In an implementation, the photoacid generator of Formula I may be included in an amount of about 20 wt % to about 50 wt %, with respect to a total weight of the photosensitive resin, e.g., about 25 wt % to about 45 wt %, or about 30 wt % to about 40 wt %. If the amount of the photoacid generator were to be greater than or equal to about 50 wt % with respect to the total weight of the photosensitive resin, the uniformity of photoresist including the photoacid generator could be adversely affected. In addition, after a chemical amplification-type deprotection reaction, a reaction residue of the photoacid generator could deteriorate quality of a semiconductor device.

The solvent may include, e.g., butyl acetate, butyl propionate, ethyl lactate, methyl hydroxyacetate, ethyl hydroxyacetate, butyl hydroxyacetate, methyl methoxyacetate, ethyl methoxyacetate, butyl methoxyacetate, methyl ethoxyacetate, ethoxyethyl acetate, methyl 3-oxypropionate, ethyl 3-hydroxypropionate, methyl 3-methoxypropionate, ethyl 3-methoxypropionate, methyl 3-ethoxypropionate, ethyl 3-ethoxypropionate, methyl 2-hydroxypropionate, propyl 2-hydroxypropionate, methyl 2-methoxypropionate, ethyl 2-methoxypropionate, propyl 2-methoxypropionate, methyl 2-ethoxypropionate, ethyl 2-ethoxypropionate, 2-hydroxy-2-methylpropionate methyl, 2-hydroxy-2-methylpropionate ethyl, 2-methoxy-2-methylpropionate methyl, 2-ethoxy methylpropionate ethyl, methyl pyruvate, ethyl pyruvate, propyl pyruvate, methyl acetoacetate, ethyl acetoacetate, 2-oxobutanoate methyl, 2-oxobutanoate ethyl, dioxane, ethylene glycol, diethylene glycol, triethylene glycol, propylene glycol, dipropylene glycol, tripropylene glycol, 1,4-butanediol, ethylene glycol monoisopropyl ether, ethylene glycol monobutyl ether, propylene glycol monomethyl ether, propylene glycol monomethyl ether acetate, propylene glycol monoethyl ether acetate, propylene glycol monopropyl ether acetate, ethylene glycol monobutyl ether acetate, cyclohexanone, cyclopentanone, diethylene glycol monomethyl ether, diethylene glycol monomethyl ether acetate, diethylene glycol monoethyl ether, diethylene glycol monoethyl ether acetate, diethylene glycol monobutyl ether, diethylene glycol monobutyl ether acetate, diethylene glycol dimethyl ether, diethylene glycol diethyl ether, diethylene glycol methyl ethyl ether, toluene, xylene, γ-butyrolactone, N,N-dimethylacetamide, or mixtures thereof.

In an implementation, the material of the photoresist may further include a leveling agent and a surfactant, as needed. Examples of the leveling agent and the surfactant may include fluoroalkylbenzenesulfonate, fluoroalkylcarboxylate, fluoroalkylpolyoxyethylene ether, fluoroalkylammonium iodide, fluoroalkyl betaine, fluoroalkyl sulfonate, diglycerin tetrakis (fluoroalkyl polyoxyethylene ether), fluoroalkyl trimethylammonium salt, fluoroalkylaminosulfonate, polyoxyethylene nonylphenyl ether, polyoxyethylene octylphenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene laurylamine, sorbitan laurate, sorbitan palmitate, sorbitan stearate, sorbitanolate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzenesulfonate, alkyldiphenyletherdisulfonate, and the like.

In an implementation, the material of the photoresist may further include an adhesion improver, as needed, to increase adhesion to a substrate. The adhesion improver may include a silane, aluminum, or titanate compound. In an implementation, the adhesion improver may include 3-glycidoxypropyldimethylethoxysilane, 3-glycidoxypropylmethyldiethoxysilane, 3-glycidoxypropyltrimethoxysilane, acetoalkoxyaluminum diisopropylate, tetraisopropylbis(dioctyl phosphite) titanate, or the like.

In an implementation, the material of the photoresist may further include a crosslinking agent, as needed.

The crosslinking agent may be a nitrogen-containing compound having at least two crosslinking substituents (e.g., a methylol group, a methoxymethyl group, or a butoxymethyl group). In an implementation, the crosslinking agent may include, e.g., hexamethoxymethylmelamine, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, 1,1,3,3-tetrakis(methoxymethyl)urea, or the like.

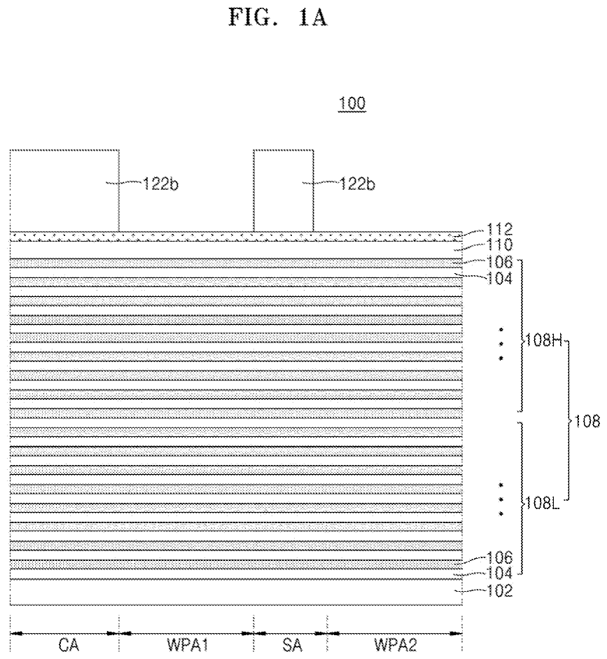

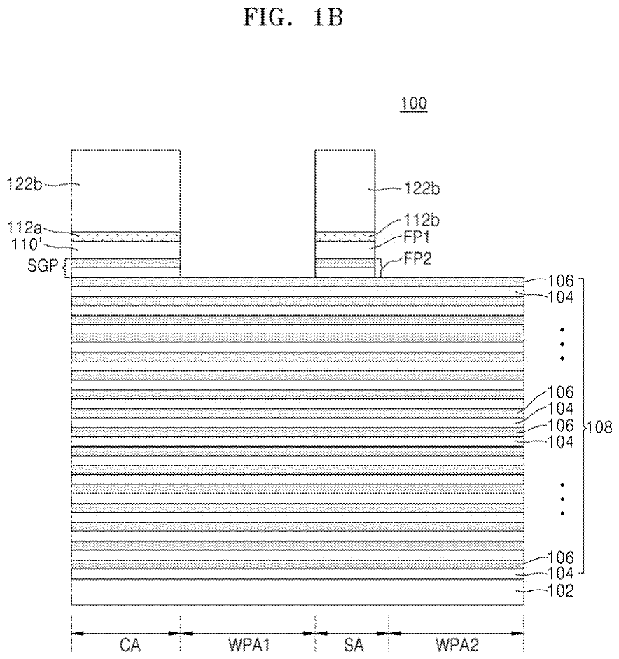

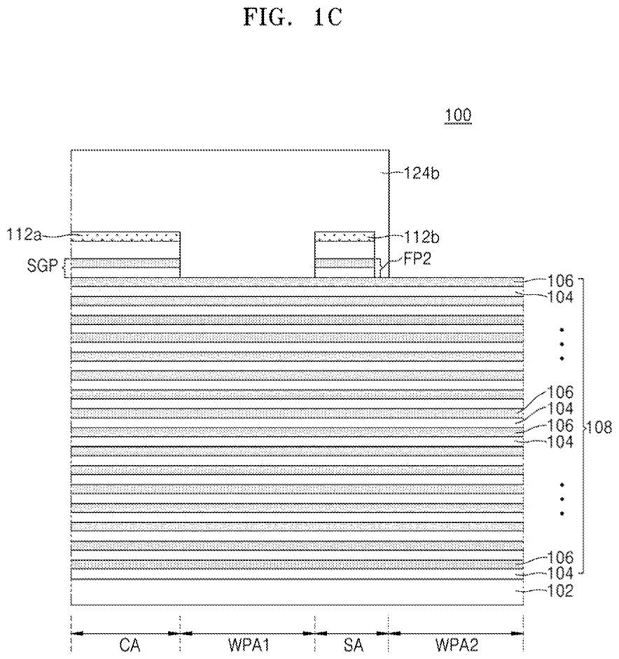

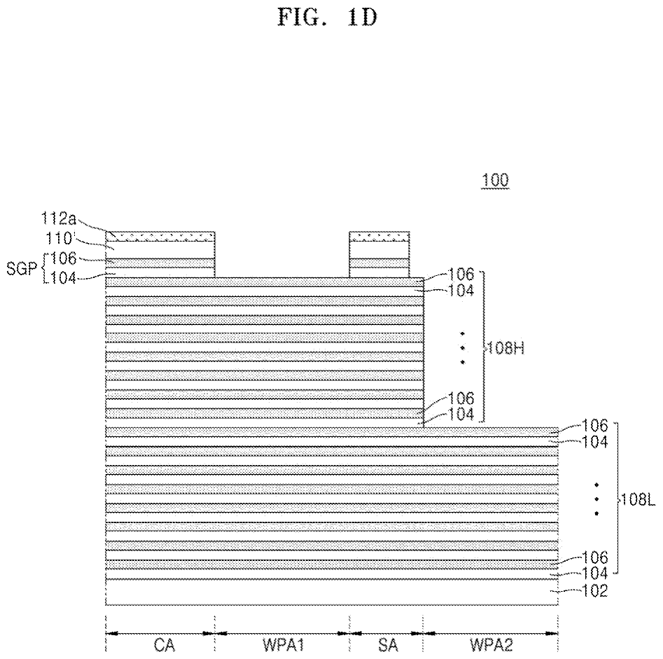

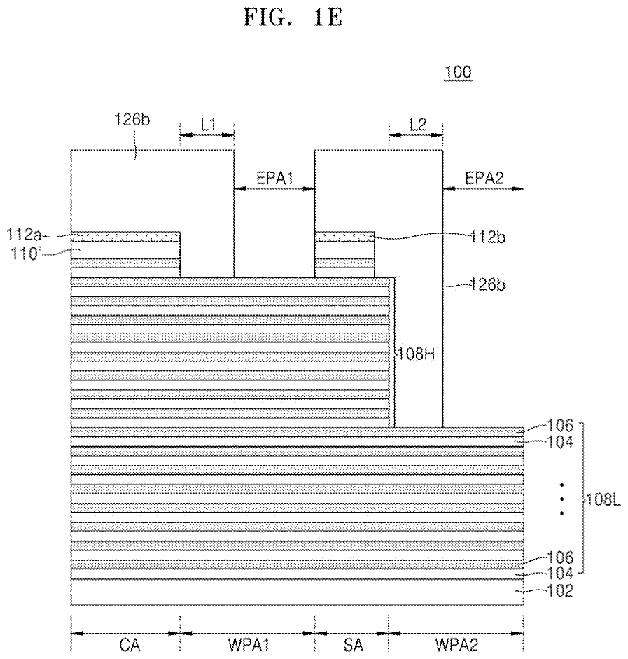

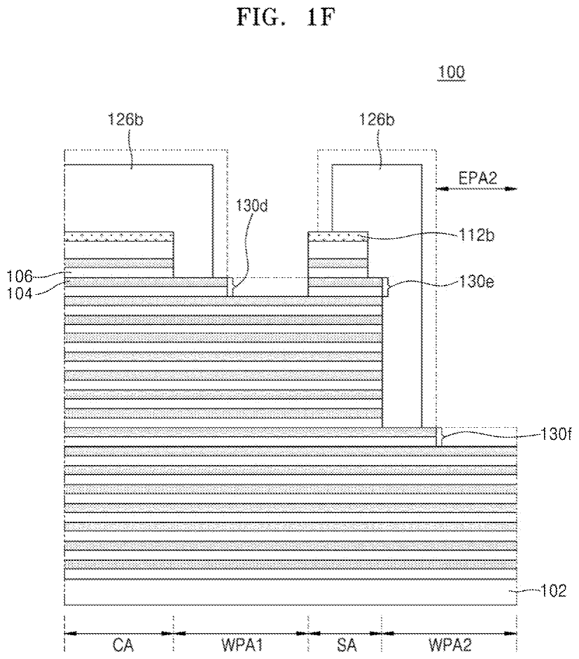

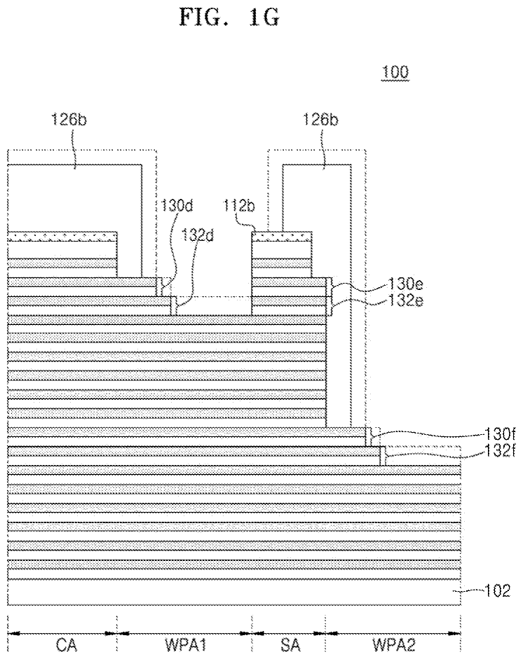

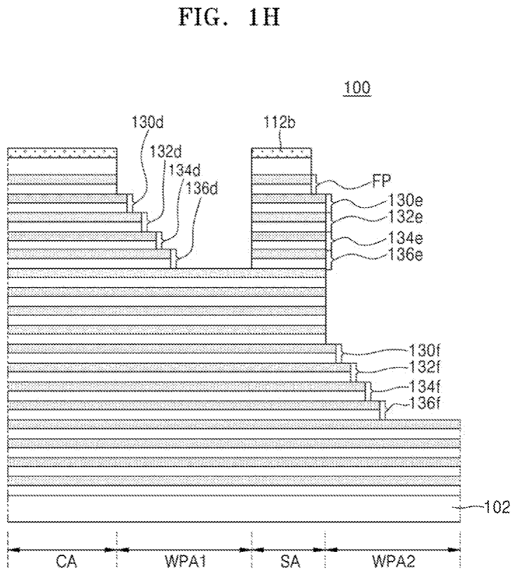

FIGS. 1A through 1H are cross-sectional views of stages in a method of manufacturing a vertical semiconductor device 100, according to an embodiment.

Referring to FIG. 1A, a stacked structure 108 and a first capping layer 110 may be sequentially stacked on a substrate 102 including a cell area CA, a sacrificial area SA, a first pad area WPA1, and a second pad area WPA2, and a polysilicon layer 112 is formed on the first capping layer 110. Next, first masks 122b may be formed on the polysilicon layer 112.

The stacked structure 108 may include an upper stacked structure 108H and a lower stacked structure 108L. The upper stacked structure 108H and the lower stacked structure 108L may each include interlayer insulating layers 104 and sacrificial layers 106 which are alternately stacked. The interlayer insulating layers 104 may be formed of an insulating material, e.g., silicon oxide. The sacrificial layers 106 may be formed of a material having etch selectivity with respect to the interlayer insulating layers 104, e.g., silicon nitride layers, silicon oxynitride layers, polysilicon layers, or polysilicon germanium layers. In an implementation, the first capping layer 110 may be formed of silicon oxide.

The polysilicon layer 112 may be formed by a method of depositing an amorphous silicon layer and then applying constant heat thereto.

The first masks 122b may be formed of a photoresist layer formed by using a photoresist material including a photoacid generator according to embodiments. An area of the stacked structure 108 to be etched may be defined by the first masks 122b. In an implementation, as described above, a photoacid generator according to embodiments may have high transparency, may absorb a small amount of light during exposure, and thus may obtain a pattern having a clear resolution despite the first masks 122b having the great thickness.

Referring to FIG. 1B, a first etching process may be performed to remove the polysilicon layer 112 in the first pad area WPA1 and the second pad area WPA2, the first capping layer 110 thereunder, and the sacrificial layer 106 and the interlayer insulating layer 104 thereunder.

Due to the first etching process, a first polysilicon pattern 112a, a spare string selection gate SGP, and a capping pattern 110′ may be formed in the cell area CA, and a second polysilicon pattern 112b, a first floating pattern FP1 thereunder, and a second floating pattern FP2 thereunder may be formed in the sacrificial area SA.

Thereafter, the second polysilicon pattern 112b may operate as an etch stop pattern that prevents a lower layer from being etched during a step forming process, and thus will be referred to as an etch stop pattern 112b hereinafter.

Referring to FIG. 1C, a second mask 124b may be formed on the cell area CA, the first pad area WPA1, and the sacrificial SA. The second mask 124b may be formed of a photoresist layer formed by using a photoresist material including a photoacid generator according to embodiments.

Referring to FIG. 1D, the upper stacked structure 108H corresponding to the second pad area WPA2 may be removed, and the second mask 124b may be removed. Therefore, only the lower stacked structure 108L may remain in the second pad area WPA2.

The second mask 124b may need to endure such that the cell area CA, the first pad area WPA1, and the sacrificial area SA are not exposed until the upper stacked structure 108H is all removed, and thus may have a sufficient thickness. If a photoresist material layer forming the second mask 124b were to absorb too much light during exposure, a pattern may not be obtained at a high resolution.

Referring to FIG. 1E, third masks 126b may be respectively formed to cover the entire portion of the cell area CA and a portion L1 of the first pad area WPA1, and simultaneously cover the entire portion of the sacrificial area SA and a portion L2 of the second pad area WPA2.

The third masks 126b may be formed of a photoresist layer formed by using a photoresist material including a photoacid generator according to embodiments.

Blocking lengths of the portion L1 of the first pad area WPA1 and the portion L2 of the second area WPA2 respectively covered by the third masks 126b may each be equal to or greater than a value obtained by multiplying an exposed horizontal length of steps to be formed later and the number of steps.

An area of the first pad area WPA1, which is not covered by the third mask 126b, may be referred to as a first exposed area EPA1, and an area of the second pad area WPA2, which is not covered by the third mask 126b, is referred to as a second exposed area EPA2.

Referring to FIG. 1F, the first etching process for forming first patterns 130d and 130f exposed in the first pad area WPA1 and the second pad area WPA2 may be included.

The first etching process may include removing the sacrificial layer 106 exposed to the first exposed area EPA1 and the second exposed area EPA2, and the interlayer insulating layer 104 thereunder, respectively, and simultaneously downsizing upper surfaces and sides of the third masks 126b. Accordingly, first patterns 130d, 130e, and 130f may be respectively formed in the first pad area WPA1, the sacrificial area SA, and the second pad area WPA2, and simultaneously, ends of the first patterns 130d and 130f may be exposed in the first pad area WPA1 and the second pad area WPA2. The first pattern 130e, which is separated from the first pattern 130d in the first pad area WPA1, may be formed in the sacrificial area SA, and one side of the first pattern 130e that is separated may be vertically aligned with one side of the etch stop pattern 112b.

Referring to FIG. 1G, a second etching process for forming second patterns 132d, 132e, and 132f underneath the first patterns 130d, 130e, and 130f, i.e., a step forming process, may be included.

Due to the second etching process, the second patterns 132d, 132e, and 132f may be formed underneath the first patterns 130d, 130e, and 130f in the first pad area WPA1, the sacrificial area SA, and the second pad area WPA2, and simultaneously, ends of the first patterns 130d and 130f and the second patterns 132d and 132f may be formed in a stepped shape in the first pad area WPA1 and the second pad area WPA2, and ends of the second patterns 132d and 132f may be exposed to the sides of the third masks 126b.

In the sacrificial area SA, the second pattern 132e, which is separated from the second pattern 132d in the first pad area WPA1, may be formed, and one side of the second pattern 132e adjacent to the first pad area WPA1 may be vertically aligned with one side of the first pattern 130e thereon.

Referring to FIG. 1H, according to the result of the multi-order etching process (i.e., the step forming process) using the third masks 126b, described above, the first patterns 130d and 130f, the second patterns 132d and 132f, third patterns 134d and 134f, and fourth patterns 136d and 136f may be simultaneously formed in the first pad area WPA1 and the second pad area WPA2. The first, second, third, and fourth patterns 130e, 132e, 134e, and 136e in the sacrificial area SA may be formed such that sides thereof adjacent to the first pad area WPA1 may be vertically aligned with one another. The vertical alignment of the sides of the first, second, third, and fourth patterns 130e, 132e, 134e, and 136e may be achieved because the etch stop pattern 112b remains in the sacrificial area SA, unlike in the first pad area WPA1 and the second pad area WPA2, and thus, the first, second, third, and fourth patterns 130f, 132f, 134f, and 136f thereunder are no longer etched.

By way of summation and review, the efficiency of a chemical amplification-type deprotection reaction could be lowered in an EUV exposure process. Therefore, a large amount of photoacid generator (PAG) may be added. However, when a large amount of photoacid generator is added, the uniformity of a photoresist including the same could deteriorate, and light absorption could increase, thereby lowering transmittance. A method may be capable of obtaining a pattern having a high resolution, while maintaining the uniformity of a photoresist and not increasing light absorption.

One or more embodiments may provide a photoacid generator including an acid amplifier.

One or more embodiments may provide a photoacid generator capable of obtaining a pattern having a high resolution, while maintaining the uniformity of photoresist and not increasing light absorption.

One or more embodiments may provide a photoresist composition capable of obtaining a pattern having a high resolution, while maintaining the uniformity thereof and not increasing light absorption.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoacid generator (PAG) represented by Formula I below, 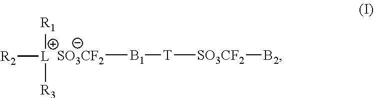
wherein in Formula I,
L is S or I, and when L is I, R₃ is omitted,
R₁, R₂, and R₃ are each independently a C1 to C10 alkyl group, C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom,
two of R₁, R₂, and R₃ are bonded to each other to form a ring together with L,
B₁ includes two or more ester groups, and is a monovalent or divalent hydrocarbon group which is substituted with a heteroatom or intervened with a heteroatom,
B₂ is a monovalent or divalent C1 to C20 hydrocarbon group which is substituted with a heteroatom or intervened with a heteroatom, and
T is an acid-sensitive group.

2. The photoacid generator as claimed in claim 1, wherein:
the photoacid generator represented by Formula I is represented by Formula II below, 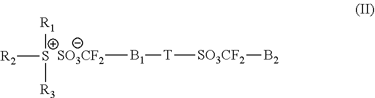
in Formula II, R₁, R₂, R₃, B₁, B₂, and T are defined the same as those of Formula I.

3. The photoacid generator as claimed in claim 1, wherein:
the photoacid generator represented by Formula I is represented by Formula III below, 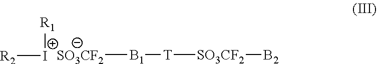
in Formula III, R₁, R₂, B₁, B₂, and T are defined the same as those of Formula I.

4. The photoacid generator as claimed in claim 1, wherein T is desorbed from B₁ and —SO₃ groups of Formula I in response to exposure to an acid.

5. The photoacid generator as claimed in claim 4, wherein T provides H⁺.

6. The photoacid generator as claimed in claim 1, wherein:
T is a group represented by Formula T below, 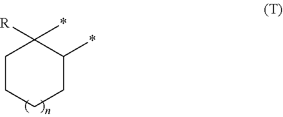
in Formula T, n is an integer of 0 to 10 and * is a bonding location to an adjacent atom.

7. The photoacid generator as claimed in claim 1, wherein:
B₁ is a group represented by Formula B1a, Formula B2a, Formula B3a, or Formula B4a, below, 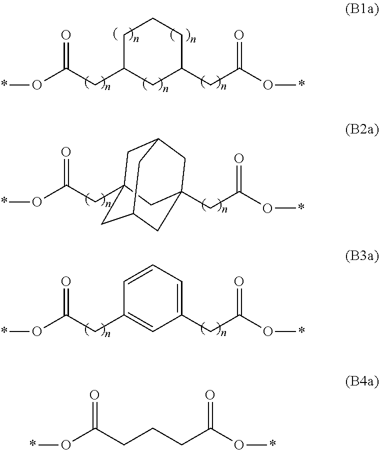
in Formula B1a, Formula B2a, Formula B3a, and Formula B4a, each n is independently an integer 0 to 10 and * is a bonding location to an adjacent atom.

8. A photoacid generator represented by Formula IV below, 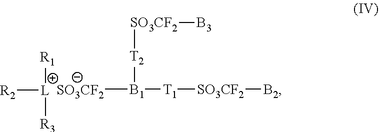
wherein in Formula IV,
L is S or I, and when L is I, R₃ is omitted,
R₁, R₂, and R₃ are each independently a C1 to C10 alkyl group, a C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom,
two of R₁, R₂, and R₃ are bonded to each other to form a ring together with L,
B₁ includes three or more ester groups, and is a monovalent or divalent hydrocarbon group which is substituted with a heteroatom or intervened with a heteroatom,
B₂ and B₃ are each independently a monovalent or divalent C1 to C20 hydrocarbon group which is substituted with a heteroatom or intervened with a heteroatom, and
T₁ and T₂ are each independently an acid-sensitive group.

9. The photoacid generator as claimed in claim 8, wherein:
the photoacid generator represented by Formula IV is represented by Formula V, below, 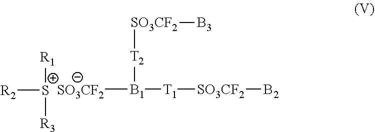
in Formula V, R₁, R₂, R₃, B₁, B₂, B₃, T₁, and T₂ are defined the same as those of Formula IV.

10. The photoacid generator as claimed in claim 8, wherein:
the photoacid generator represented by Formula IV is represented by Formula VI, below, 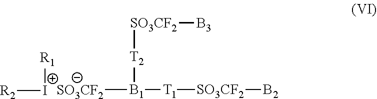
in Formula VI, R₁, R₂, B₁, B₂, B₃, T₁, and T₂ are defined the same as those of Formula IV.

11. The photoacid generator as claimed in claim 8, wherein:
T₁ and T₂ are each independently a group represented by Formula T, below, 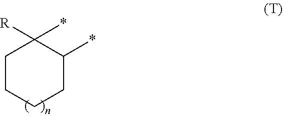
in Formula T, n is an integer of 0 to 10.

12. The photoacid generator as claimed in claim 8, wherein:
B₁ is a group represented by Formula B1b, Formula B2b, Formula B3b, Formula B4b, Formula B5b, or Formula B6b, below, 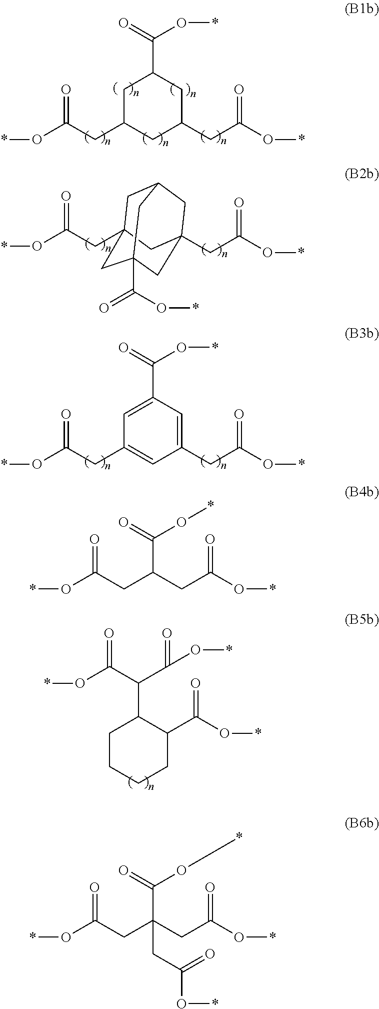
in Formula B1b, Formula B2b, Formula B3b, Formula Bob, Formula B5b, and Formula B6b, each n is independently an integer of 0 to 10.

13. A photoresist composition, comprising:
a photosensitive resin;
a photoacid generator represented by Formula I, below; and
a solvent capable of dissolving the photosensitive resin and the photoacid generator, 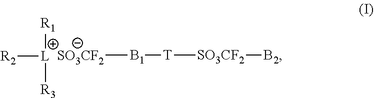
wherein in Formula I,
L is S or I, and when L is I, R₃ is omitted,
R₁, R₂, and R₃ are each independently a C1 to C10 alkyl group, C1 to C10 alkoxy group, a C2 to C10 alkenyl group, a C2 to C10 alkynyl group, a C6 to C18 aryl group, a C7 to C18 arylalkyl group, or a C7 to C18 alkylaryl group, each of which is substituted with a heteroatom or intervened with a heteroatom,
two of R₁, R₂, and R₃ are bonded to each other to form a ring together with L,
B₁ includes two or more ester groups, and is a monovalent or divalent hydrocarbon group which is substituted with a heteroatom or intervened with a heteroatom,
B₂ is a monovalent or divalent C1 to C20 hydrocarbon group which is substituted with a heteroatom or intervened with a heteroatom, and
T is an acid-sensitive group.

14. The photoresist composition as claimed in claim 13, wherein the photoresist composition does not include a separate acid amplifier.

15. The photoresist composition as claimed in claim 13, wherein:
the photoacid generator represented by Formula I forms two acids with respect to one photon, and
the one photon is a unit of light having minimum energy for dissociation of one SO₃⁻S⁺(R₁R₂R₃) or SO₃⁻I⁺(R₁R₂) to convert the one SO₃⁻S⁺(R₁R₂R₃) or SO₃⁻I⁺(R₁R₂) to one SO₃⁻H⁺.

16. The photoresist composition as claimed in claim 13, further comprising a quencher.

17. The photoresist composition as claimed in claim 13, wherein the photosensitive resin is reactive to extreme ultraviolet light.

18. The photoresist composition as claimed in claim 13, wherein:
the photoacid generator represented by Formula I is represented by Formula II below, 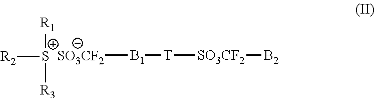
in Formula II, R₁, R₂, R₃, B₁, B₂, and T are defined the same as those of Formula I.

19. The photoresist composition as claimed in claim 13, wherein:
the photoacid generator represented by Formula I is represented by Formula III below, 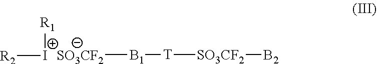
in Formula III, R₁, R₂, B₁, B₂, and T are defined the same as those of Formula I.

20. The photoresist composition as claimed in claim 13, wherein the photoacid generator is included in the composition in an amount of 20 wt % to 50 wt %, based on a total weight of the photosensitive resin.
